(19) United States
(12) Patent Application Publication
(10) Pub. No.: US 2005/0110118 A1
(43) Pub. Date: May 26, 2005

(54) Scribe seal providing enhanced substrate noise isolation

(75) Inventors: Anand Hariraj Udupa, Bangalore (IN); Selvaraj Raja, Bangalore (IN); Shakthi Shankar Rath, Bangalore (IN)

Correspondence Address: TEXAS INSTRUMENTS INCORPORATED, P O BOX 655474, M/S 3999, DALLAS, TX, 75265, US

(73) Assignee: Texas Instruments Incorporated, Dallas, TX (US)

(21) Appl. No.: 10/723,114

(22) Filed: Nov. 26, 2003

(51) Int. Cl. H01L 21/30; H01L 23/544

(52) U.S. Cl. 257/620; 438/458

(57) ABSTRACT

Multiple scribe seals are provided around an integrated circuit on a die to attain enhanced substrate noise isolation. In one embodiment, an inner scribe seal prevents mobile ions from entering the integrated circuit, and an outer scribe seal provides mechanical strength to the die. In addition, both the inner scribe seal and the outer scribe seal are designed to offer high resistance path to substrate noise. Due to the high resistance, the noise that would be coupled to various portions of the integrated circuit may be reduced.

### BACKGROUND OF THE INVENTION

1. Field of the Invention

The present invention relates to integrated circuits, and more specifically to a scribe seal providing enhanced substrate noise isolation.

2. Related Art

A scribe seal is often provided around an integrated circuit (ICs) implemented on a common substrate of a die. The scribe seal generally provides mechanical strength to the die, and also may serve other purposes. For example, scribe seals prevent mobile ions from entering into the integrated circuit.

One common problem encountered with ICs is the introduction of noise from various sources. Scribe seal also provides a medium for carrying such noise, generally due to the inherent low resistance along the substrate at least in several prior embodiments. The noise thus carried may interfere with the operation of portion(s) of the IC. Accordingly, it is desirable to provide a scribe seal which provides for enhanced substrate noise isolation.

### BRIEF DESCRIPTION OF THE DRAWINGS

The present invention will be described with reference to the following accompanying drawings described briefly below.

FIG. 1 is a diagram illustrating the details of a wafer containing multiple dies in one embodiment.

FIG. 2A is a block diagram illustrating the details of a die in one embodiment.

FIG. 2B is a logical diagram illustrating the manner in which a prior scribe seal provides a low resistance path along the substrate.

FIG. 3 illustrates the conventions used to represent various layers in the layout structures.

FIG. 4 is a top-view of the layout structure of a prior scribe seal in one embodiment.

FIG. 5 is a cross-sectional view of the layout structure of a prior scribe seal.

FIG. 6 is a block diagram illustrating the details of a die in an embodiment of the present invention.

FIG. 7 is a cross-sectional view of the layout structure illustrating the details of an inner scribe seal in an embodiment of the present invention.

FIG. 8 is a cross-sectional view of the layout structure illustrating the details of an outer scribe seal in an embodiment of the present invention.

FIG. 9 is a cross-sectional view of the layout structure illustrating the details of an outer scribe seal in an alternative embodiment of the present invention.

FIG. 10 is a top view of the layout structure illustrating the details of an inner scribe seal.

FIG. 11 is a top view of the layout structure illustrating the details of an outer scribe seal.

FIG. 12 is a flowchart illustrating the manner in which a die (containing an integrated circuit) may be manufactured according to an aspect of the present invention.

In the drawings, like reference numbers generally indicate identical, functionally similar, and/or structurally similar elements. The drawing in which an element first appears is indicated by the leftmost digit(s) in the corresponding reference number.

### DETAILED DESCRIPTION OF THE PREFERRED EMBODIMENTS

1. Overview

Multiple scribes are used around an integrated circuit of a die on a common substrate to attain increased substrate noise isolation. In one embodiment, an inner scribe seal is designed to prevent mobile ions from entering the integrated circuit and an outer scribe seal is designed to provide mechanical strength to the die. Both of inner scribe seal and outer scribe seal are implemented to provide high resistive path to substrate noise. Due to the high resistance path, the noise that would (otherwise) be coupled to various portions of the integrated circuit through common substrate may be reduced.

Several aspects of the invention are described below with reference to examples for illustration. It should be understood that numerous specific details, relationships, and methods are set forth to provide a full understanding of the invention. One skilled in the relevant art, however, will readily recognize that the invention can be practiced without one or more of the specific details, or with other methods, etc. In other instances, well known structures or operations are not shown in detail to avoid obscuring the invention.

Various features of the present invention may be appreciated better by understanding an example embodiment in which such scribe seal is not implemented. Accordingly, such an example embodiment is described below. First, the details of a general wafer are described.

2. Wafer

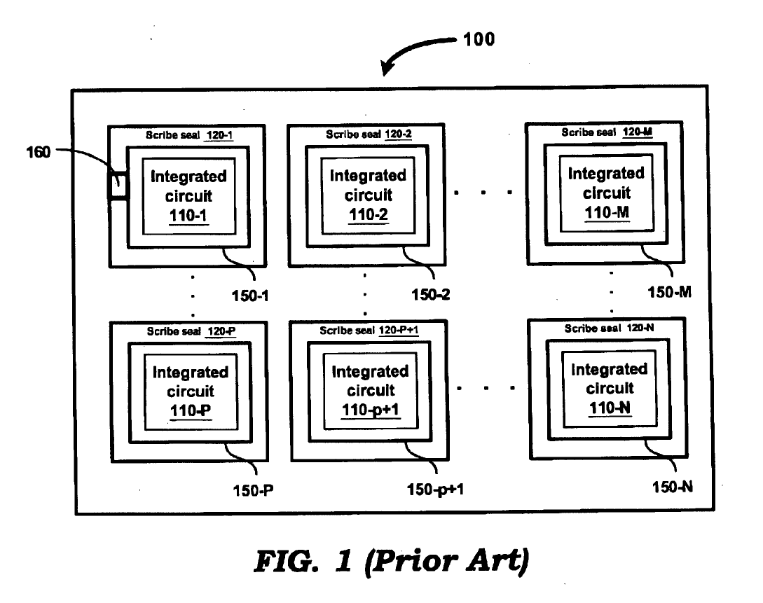

FIG. 1 is a diagram illustrating the details of a wafer (shown as rectangle merely for convenience) in one prior embodiment. Wafer 100 is shown containing multiple dies 150-1 through 150-N. Each of dies 150-1 through 150-N is shown containing a corresponding one of integrated circuits 110-1 through 110-N and corresponding one scribe seals 120-1 through 120-N.

Integrated circuits 110-1 through 110-N are shown circumscribed by scribe seals 120-1 through 120-N respectively. Portion 160 of scribe seal 120-1 is used in Figures below to illustrate the details of a layout structure of a prior scribe seal. It should be appreciated that other portions of scribe seal 120-1 may be implemented similar to portion 160.

Scribe seals 120-1 through 120-N provide mechanical strength to integrated circuits 110-1 through 110-N respectively. The mechanical strength may avoid any cracks due to cutting when each die is separated from the wafer. In addition, scribe seals 120-1 through 120-N prevent any mobile ions from entering into integrated circuits 110-1 through 110-N respectively, which may otherwise interfere with the operation of various transistors in the integrated circuit.

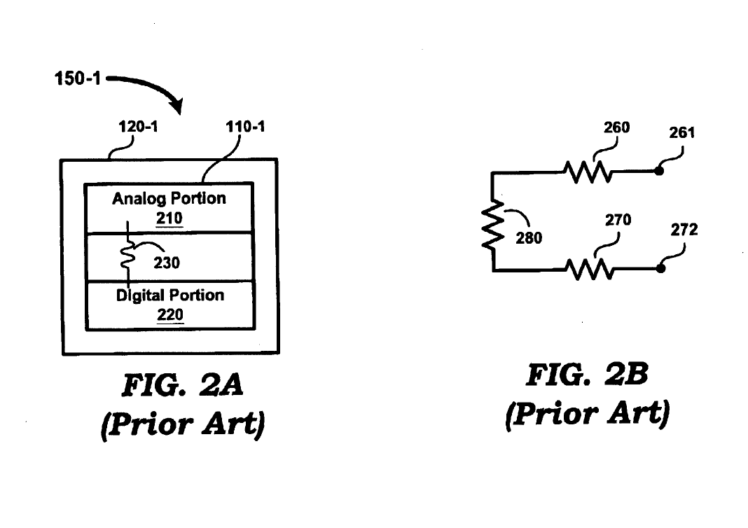

Various aspects of the present invention will be clearer by understanding the problems with the scribe seals of FIG. 1. Accordingly, the problems associated with an example die are described below with reference to FIGS. 2A and 2B.

3. Die

FIG. 2A is a block diagram illustrating the details of die 150-1 in one prior embodiment. Die 150-1 is shown containing integrated circuit 110-1 and scribe seal 120-1. Integrated circuit 110-1 is further shown containing analog portion 210, digital portion 220 and resistor 230. Analog portion 210 contains all analog circuits and digital portion contains all digital circuits of integrated circuit 110-1. Resistor 230 logically represents the resistance of the common substrate between analog portion 210 and digital portion 220.

One problem with containing both analog and digital circuits is that digital portion 220 may generate noise (e.g., due to fast transitions from one logical value to the other) which may disturb the operation of various analog circuits in analog portion 210. The noise may be coupled to analog portion 210 through supply and ground.

In one prior approach, such noise is sought to be reduced by using separate supply and ground for analog portion 210 and digital portion 220. However, additional noise will still be present since both digital and analog portions are implemented using a common substrate, which may couple the noise through substrate resistor 230. In addition to substrate resistance, scribe seal 120-1 offers low resistance as described below with reference to FIG. 2B.

FIG. 2B is a logical diagram illustrating the manner in which a scribe seal may provide a low resistance path between different portions of an integrated circuit. The logical diagram is shown containing resistors 260, 270 and 280. Resistor 260 logically represents the resistance of the connecting portion of scribe seal 120-1 to substrate in analog portion 210. Resistor 270 logically represents the resistance of the connecting portion of scribe seal 120-1 to substrate in digital portion 220. Resistor 280 logically represents the resistance of metal layers used in manufacturing scribe seal 120-1. Thus, the resistance offered by the scribe seal equals the sum of resistance of resistors 260, 270 and 280.

In general, metal layers forming scribe seal 120-1 are laid as thick layers, which cause a low resistance of resistor 280. Similarly, resistors 260 and 270 also provide low resistance since scribe seal 120-1 is provided around integrated circuit 150-1. As a result, the resistance of scribe seal 120-1 between nodes 261 and 271 (which connect to substrate in analog portion 210 and digital portion 220) is small. Due to the low resistance path in the substrate between analog portion 210 and digital portion 220, the noise may be coupled from one portion to the other (e.g., from digital portion 220 to analog portion 210).

One approach to reduce noise due to low resistance path caused by substrate and scribe seal is to increase the resistance of the substrate. The increase in resistance of the substrate causes the circuits more prone to “latch up” (leading to drawing of high amount of current) as is well known in relevant arts. In addition, the cost of the process may also increase.

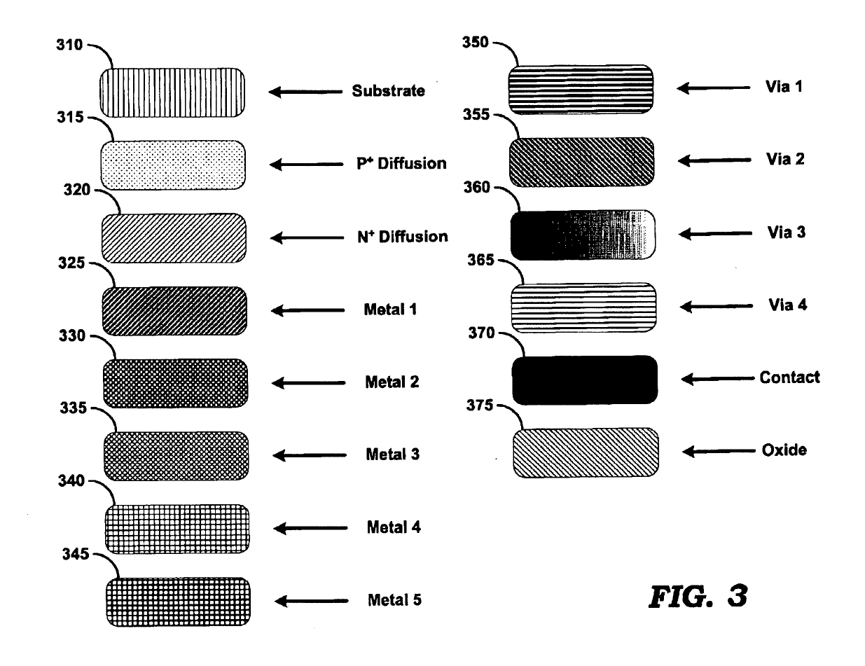

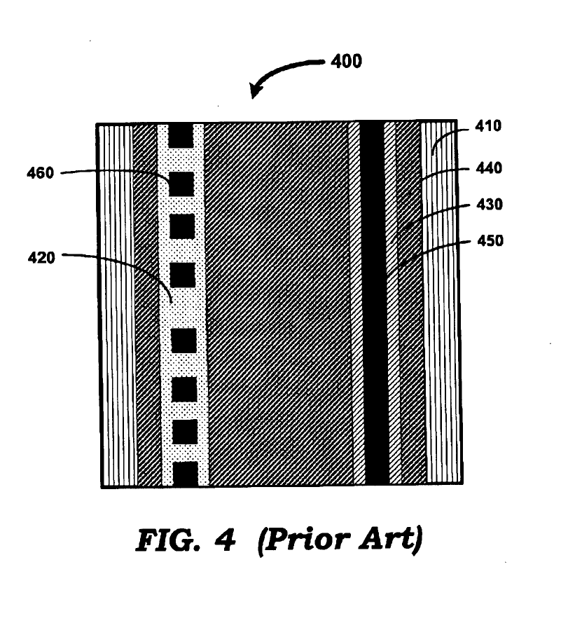

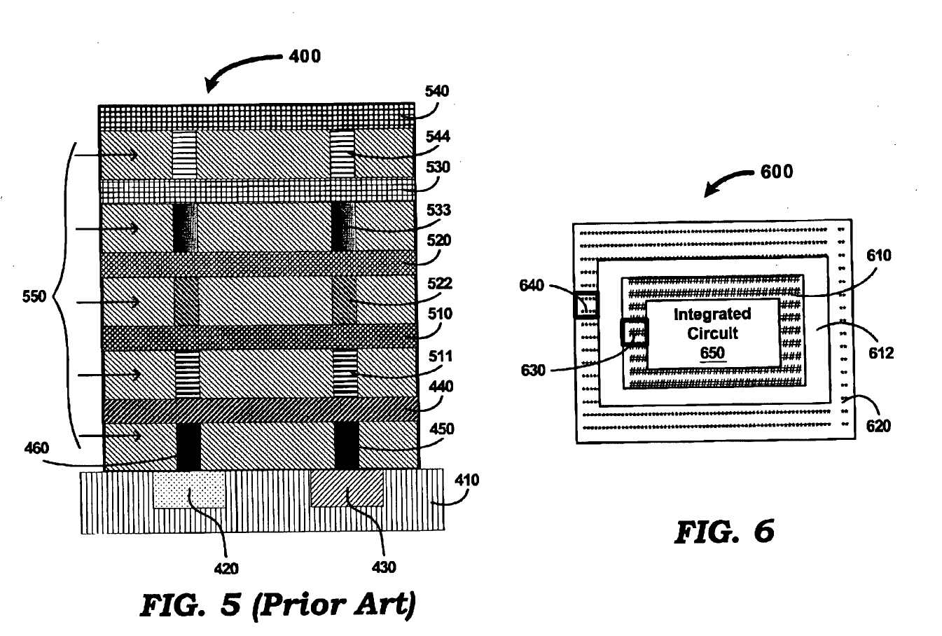

Various aspects of the present invention enable the implementation of scribe seals providing enhanced substrate noise isolation. Some aspects of the present invention will be clearer by understanding the implementation of a prior scribe seal. Accordingly, a prior scribe seal is described below with reference to FIGS. 4 and 5. First, an example convention used to represent various layers forming the scribe seal is described below with reference to FIG. 3.

4. Convention

In FIG. 3, the substrate, P⁺ diffusion, N⁺ diffusion, metal1, metal2, metal 3, metal 4, metal 5, via 1, via 2, via 3, via 4, contact and oxide are respectively represented by patterns 310, 315, 320, 325, 330, 335, 340, 345, 350, 355, 360, 365, 370, and 375 respectively. This convention is attempted to be used in all the drawings below related to layout structures. The description is continued with reference to an example prior scribe seal.

5. Prior Scribe Seal Which Does Not Implement One or More Features of the Present Invention

FIGS. 4 and 5 are layout structures illustrating the details of one prior scribe seal. In particular, FIG. 4 depicts layout structure 400 of portion 160 in top view and FIG. 5 depicts layout structure 400 of portion 160 in cross-sectional view.

Continuing with reference to FIG. 4, layout structure 400 is shown containing substrate 410, P+diffusion 420, N+diffusion 430, metal 1 layer 440, continuous contacts 450, and periodic contacts 460.

As is well known in relevant arts, a contact layer provides connection between diffusion layer and metal1 layer. It may be observed that continuous stream of contacts 450 are provided to connect N+diffusion layer 430 to metal 1 layer 440 and periodic contacts are provided to connect P+diffusion layer 420 to metal 1 layer 440.

Layout structure 400 is shown containing only metal1 layer 440, however, layout structure 400 often contains more metal layers. In addition, metal1 layer 440 may cover diffusion layers 420/430 and contact layer, even though the covered layers are shown in the diagram merely for understandability. Via layers may be used to provide connection between metal layers through oxide layer, which is further described in sections below with reference to FIG. 5.

The metal, Via and contact layers in the scribe seal provide a continuous wall which blocks the entry of mobile ions through the oxide. Metal 1 layer 440 is implemented as a thick layer, and thus enables layout structure 400 to provide high/acceptable mechanical strength. The description is continued with reference to cross sectional view of layout structure 400.

FIG. 5 is a layout structure illustrating the details of layout structure 400 in cross sectional view. Layout structure 400 is shown containing metal2 layer 510, metal3 layer 520, metal4 layer 530, metal 5 layer 540, oxide layer 550, via1 layer 511, via2 layer 522, via3 layer 533, and via4 layer 544 in addition to the layers shown in FIG. 4.

As is well known in relevant arts, a Via layer is used to provide connections between different metal layers. Vial layer 511 is used to connect metal 2 layer 510 to metal 1 layer 440, via2 522 is used to connect metal 3 520 to metal 2 510, via3 533 is used to connect metal 4 530 to metal 3 520, and via4 544 is used to connect metal 4 530 to metal 5 540.

Oxide layers 550 are used between the adjacent metal layers to separate the metal layers from one another. Via layers are deposited after removing the portions of oxide layers 550 to provide connection between different metal layers. As a result, it may be appreciated that the scribe seal may provide a complete wall in the oxide.

As described above, layout structure 400 provides good mechanical strength due to thick metal layers and prevents mobile ions from entering the integrated circuit due to the continuous wall in the oxide. However, thick metal layer (logically represented by resistor 280 of FIG. 2B) offers low resistance and the conductive path (logically represented by resistors 260 and 270 of FIG. 2B) also provides low resistance to the substrate. As a result, layout structure 400 provides a low resistance path from noisy digital portion 220 to sensitive analog portion 210 which may couple noise generated in digital portion 220 to various circuits in analog portion 210. Various aspects of the present invention reduces the noise as described below.

6. Die Implementing One or More Features of the Present Invention

FIG. 6 is a block diagram illustrating the details of die 600 in an embodiment of the present invention. Die 600 is shown containing inner scribe seal 610, outer scribe seal 620 and integrated circuit 650. The two scribe seals are shown separated by gap 612. Each component is described below in detail.

Inner scribe seal 610 prevents mobile ions from entering integrated circuit 650. However, the metal layers are made thin such that inner scribe seal 610 offers high resistance.

Outer scribe seal 620 provides mechanical strength to integrated circuit 650 by providing thick metal layers. However, connection from the metal layers to substrate is removed (or not provided) such that the resistance to substrate is high.

Thus, inner scribe seal 610 and outer scribe seal 620 together perform the two functions of a general scribe seal. In addition, each of inner scribe seal 610 and outer scribe seal 620 offers high resistance path and thus the noise that would be coupled to analog portion may be reduced.

Portions 630 and 640 in inner scribe seal 610 and outer scribe seal 620 are respectively used in Figures below to illustrate various aspects of the present invention. It should be understood that other portions of scribe seal 610 (also 620) are also implemented similar to portion 630 (640).

It may be noted that inner scribe seal 610 is provided around integrated circuit 650 and outer scribe seal 620 is provided around inner scribe seal 620. Though inner scribe seal 610 is shown completely surrounding integrated circuit 650, alternative embodiments may be implemented with inner scribe seal 610 only partially surrounding integrated circuit 650. Similarly, outer scribe seal 620 may fully/partially surround inner scribe seal 610.

In addition, the layers in inner scribe seal 610 are laid differently than the layers in outer scribe seal 620. For example, the metal layers in inner scribe seal 610 are laid as thin layers and the metal layers in outer scribe seal 620 are laid as thick layers. The manner in which the layers are laid in inner scribe seal 610 and outer scribe seal 620 is described below with various examples.

7. Inner Scribe Seal

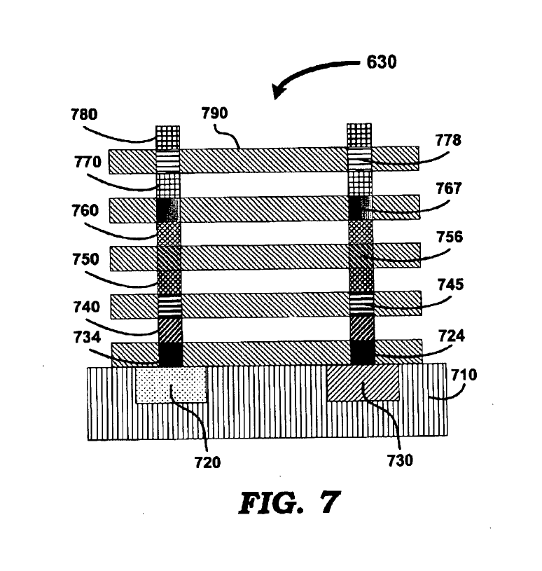

FIG. 7 is a layout structure illustrating the details of portion 630 of inner scribe seal 610 in an embodiment of the present invention. Portion 630 is shown containing substrate 710, P+ diffusion 720, N+diffusion 730, contact layers 724 and 734, metal 1 layer 740, metal2 layer 750, metal3 layer 760, metal4 layer 770, metal 5 layer 780, oxide layer 790, via1 layer 745, via2 layer 756, via3 layer 767, and via4 layer 778.

P+diffusion 720 and N+ diffusion 730 are laid on substrate 710. P+diffusion 720 and N+ diffusion 730 are high conductive layers. Contact layer 724 connects P+diffusion layer 720 to metal1 layer 740 and contact layer 734 connects N+diffusion layer 730 to metal1 layer 740.

Oxide layer 790 is deposited between the adjacent metal layers to separate the metal layers from one another. Via layers are deposited after removing the portions of oxide layers 790 to provide connection between different metal layers. For example, via1 layer 745 is used to connect metal 2 750 to metal 1 740, via2 756 is used to connect metal 3 760 to metal 2 750, via3 767 is used to connect metal 4 770 to metal 3 760, and via4 778 is used to connect metal 4 770 to metal 5 780.

As a result, the Via layers and the metal layers together provide a continuous wall through oxide layers to prevent mobile ions from entering the integrated circuit through the oxide layers. In addition, P+diffusion 720, N+diffusion 730, and contacts 724 and 734 also provide good conductive path from metal1 layer 740 to substrate 710.

In addition, portion 630 offers a high resistance due to the small width of metal layers. It may be observed that all the metal layers are deposited only on small portions corresponding to P+diffusion 720 and N+ diffusion 730. As a result of small metal width, the resistance offered by portion 630 is high as illustrated in further detail with reference to FIG. 2B.

With reference to FIG. 2B, the resistance of resistor 280 is high due to the small width of metal layers and the resistance of resistors 260 and 270 is small due to the conductive path present to the substrate. As a result, the total resistance between nodes 261 and 271 due to portion 630 is large. The description is continued with reference to outer scribe seal 620.

8. Outer Scribe Seal

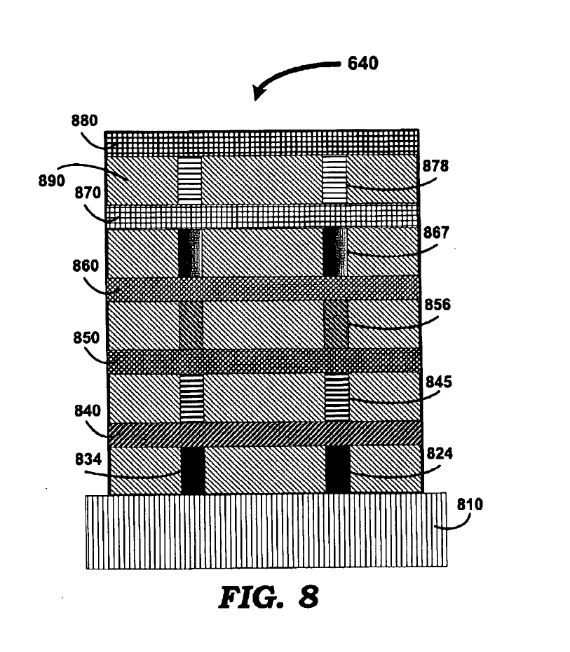

FIG. 8 is a layout structure illustrating the details of portion 640 of outer scribe seal 620 in an embodiment of the present invention. Portion 640 is shown containing substrate 810, contact layers 824 and 834, metal 1 layer 840, metal2 layer 850, metal3 layer 860, metal4 layer 870, metal 5 layer 880, oxide layer 890, via1 layer 845, via2 layer 856, via3 layer 867, and via4 layer 878.

Oxide layer 890 is deposited between the adjacent metal layers to separate the metal layers from one another. Via layers are deposited after removing portions of oxide layers 890 to provide connection between different metal layers. For example, via1 layer 845 is used to connect metal 2 850 to metal 1 840, via2 856 is used to connect metal 3 860 to metal 2 850, via3 867 is used to connect metal 4 870 to metal 3 860, and via4 878 is used to connect metal 4 870 to metal 5 880. Contact layers 824 and 834 are laid on top of substrate 810.

The metal layers are deposited as thick (more width) layers. It may be noted that metal layers are deposited with more width on substrate 810 compared to the width of metal layers in portion 630 of FIG. 7. As a result of wide metal layers, portion 640 provides good mechanical strength to integrated circuit 650.

In addition, portion 640 offers high resistance since diffusion layers (which are more conductive) are not laid and contact layers 824 and 834 provide no ohmic connection between metal layers and substrate. However, contact layers 824 and 834, and substrate 810 form a Schottky diode which is highly resistive compared to ohmic contact. As a result, the path to substrate is high resistive as illustrated with reference to FIG. 2B below.

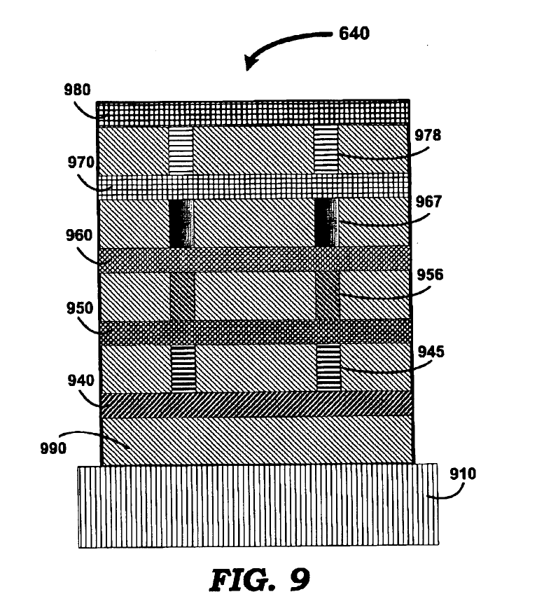

With reference to FIG. 2B, the resistance of resistor 280 is small due to the thick metal layers, however, the resistance of resistors 260 and 270 is high due to the absence of ohmic connection to the substrate. As a result, the total resistance between nodes 261 and 271 due to portion 640 is also large as desired. An alternative embodiment of portion 640 is described below in detail with reference to FIG. 9.

9. Alternative Outer Scribe Seal

FIG. 9 is a layout structure illustrating the details of portion 640 of outer scribe seal 620 in an alternative embodiment of the present invention. Portion 640 is shown containing substrate 910, metal 1 layer 940, metal2 layer 950, metal3 layer 960, metal4 layer 970, metal 5 layer 980, oxide layer 990, via1 layer 945, via2 layer 956, via3 layer 967, and via4 layer 978. Merely for conciseness, the description is provided in comparison to the embodiment of FIG. 8.

Substrate 910, metal 1 layer 940, metal2 layer 950, metal3 layer 960, metal4 layer 970, metal 5 layer 980, oxide layer 990, via1 layer 945, via2 layer 956, via3 layer 967 and via4 layer 978 are respectively described similar to substrate 810, metal 1 layer 840, metal2 layer 850, metal3 layer 860, metal4 layer 870, metal 5 layer 880, oxide layer 890, via1 layer 845, via2 layer 856, via3 layer 867, and via4 layer 878.

It may be observed that the layers corresponding to contact layers 824 and 834 are not laid. The Schottky diode, which may otherwise present between contact layers and substrate, is not formed. As a result, no ohmic and Schottky connections between metal layers and substrate are present, and thus a high resistive path to substrate 910 is present compared to portion 640 of FIG. 8.

Merely for conciseness, each of portion 640 and portion 630 is described as containing only five metal layers, however, each of portion 630 and portion 640 may contain more or less number of metal and via layers. In addition, a protective over coat is generally provided on top of the highest metal layer (metal layer in the described example embodiment), which is not shown.

It may be appreciated from the above that portion 630 prevents mobile ions from entering integrated circuit 650, and portion 640 provides good mechanical strength to integrated circuit 650. In addition, both portion 630 and portion 640 offer high resistance path to substrate noise (for different reasons, as noted above). Due to the high resistance, the noise that would be coupled to analog portion 210 of FIG. 2A may be reduced.

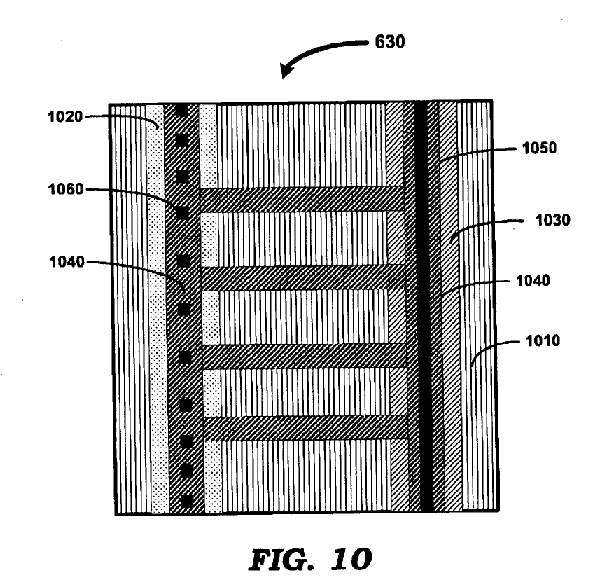

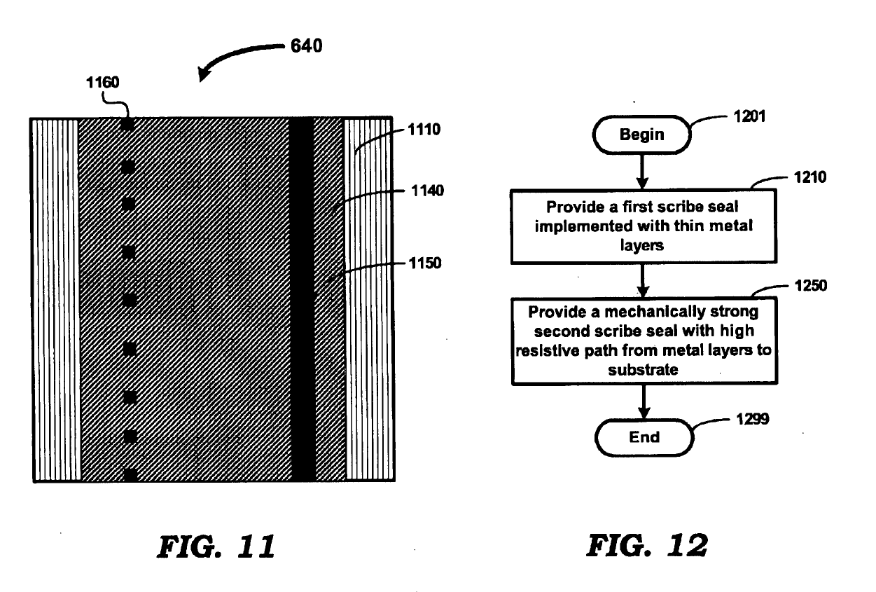

FIGS. 7, 8 and 9 illustrate a cross-sectional view of portion 630 and portion 640. The top view of portion 630 and portion 640 is described below with reference to FIGS. 10 and 11 respectively.

10. Top View of Inner Scribe Seal

FIG. 10 is a layout structure illustrating the details of a top view of portion 630 of inner scribe seal 610 corresponding to the embodiment of FIG. 7. Portion 630 is shown containing substrate 1010, P+diffusion 1020, N+diffusion 1030, metal 1 layer 1040, continuous contacts 1050, and periodic contacts 1060. Merely for conciseness, the description is provided in comparison to the embodiment of FIG. 7. In addition, the layout structure is shown containing only metal1 layer 1040, however, portion 630 may contain more number of metal layers as is well known in the relevant arts.

Substrate 1010, P+diffusion 1020, N+diffusion 1030, metal 1 layer 1040, continuous contacts 1050, and periodic contacts 1060 are respectively described similar to substrate 710, P+ diffusion 720, N+diffusion 730, metal 1 layer 740, contact layers 724 and 734.

It may be observed that continuous stream of contacts 1050 are provided to connect N+diffusion layer 1030 to metal 1 layer 1040 and periodic contacts are provided to connect P+diffusion layer 1020 to metal 1 layer 1040. The metal layers and via layers together prevent mobile ions from entering the integrated circuit.

In addition, it may be observed that metal 1 layer 1040 is deposited in some portions with small width. The small width of metal layer provides high resistive path to substrate. The description is continued with reference to top view of portion 640.

11. Alternative View of Outer Scribe Seal FIG. 11 is a layout structure illustrating the details of a top view of portion 640 in an embodiment of FIG. 8. Portion 640 is shown containing substrate 1110, metal 1 layer 1140, continuous contacts 1150, and periodic contacts 1160. Merely for conciseness, the description is provided in comparison to the embodiment of FIG. 8. In addition, the layout structure is shown containing only metal1 layer 1140, however, portion 640 contains more number of metal layers as is well known.

Substrate 1110, metal 1 layer 1140, continuous contacts 1150, and periodic contacts 1160 are respectively described similar to substrate 810, metal 1 layer 840, contact layers 824 and 834.

It may be observed that metal1 layer 1140 is deposited as a thick (wide) layer, which provides high mechanical strength to integrated circuit 650. In addition, it may be observed that diffusion layers are not laid. Due to such configuration, no ohmic connection is present between metal1 layer 1140 and substrate 1110, which provides high resistive path to substrate.

The layout structures described above can be implemented using various manufacturing technologies, as is well known in the relevant arts. The manner in which embodiments according to various aspects of the present invention can be implemented is described below.

12. Method

FIG. 12 is a flow chart illustrating the manner in which a die may be manufactured according to an aspect of the present invention. For illustration, the flow chart is described with reference to the dies described above. However, the method may be used to implement other dies as well. The method begins in step 1201, in which control immediately passes to step 1210.

In step 1210, a first scribe seal is provided around an integrated circuit on a common substrate. The first scribe seal is implemented with thin metal layers. Thin metal layers generally offer high resistance. Thus, the first scribe seal provides high resistance path to substrate noise.

In step 1250, a mechanically strong second scribe seal is provided with high resistance path from metal layers to the substrate. In an embodiment, the high resistance path is achieved by removing (or not laying) connecting paths from metal layers to substrate. For example, by removing diffusion layers (as described above with reference to FIG. 8) and/or contact layers (as described above with reference to FIG. 9), metal layers are not connected to the substrate.

As a result of the disconnecting path to substrate, the second scribe seal also provides high resistance path to substrate noise. The method ends in step 1299. It may be noted that each common layer for all of integrated circuit, first scribe seal and second scribe seal is laid once in typical manufacturing processes. Accordingly, the three components are generally implemented in parallel, even though the first scribe seal and the second scribe seal are described as being implemented sequentially.

From the above, it may be appreciated that each of the first scribe seal and second scribe seal provides high resistance path to substrate noise. Due to the high resistance path, the noise coupled to various portions of the circuits through the common substrate may be reduced.

### 13. Conclusion

While various embodiments of the present invention have been described above, it should be understood that they have been presented by way of example only, and not limitation. Thus, the breadth and scope of the present invention should not be limited by any of the above described exemplary embodiments, but should be defined only in accordance with the following claims and their equivalents.

1. A die comprising:
an integrated circuit;
a first scribe seal around said integrated circuit; and
a second scribe seal around said first scribe seal, wherein all of said integrated circuit, said first scribe and said second scribe seal are laid on a common substrate.

2. The die of claim 1, wherein said first scribe seal comprises a first plurality of layers, and said second scribe seal comprises a second plurality of layers, wherein said first plurality of layers are laid differently than said second plurality of layers on said die.

3. The die of claim 1, wherein said first scribe seal prevents entry of mobile ions into said integrated circuit, said second scribe seal provides mechanical strength to said die, and both of said first scribe seal and said second scribe seal provide respective high resistance paths along said common substrate.

4. The die of claim 3, wherein said first scribe seal comprises:
a thin metal layer to provide high resistance path; and
a metal layer and a via layer together forming a wall in an oxide layer, wherein said wall prevents the entry of said mobile ions into said integrated circuit.

5. The die of claim 4, wherein said second scribe seal comprises a thick metal layer providing mechanical strength to said die, wherein said thick metal layer is not connected to said common substrate to provide high resistance path to said common substrate.

6. The die of claim 5, wherein a diffusion layer is absent in said second scribe seal.

7. The die of claim 6, wherein a contact layer is absent in said second scribe seal.

8. The die of claim 5, wherein said integrated circuit comprises an analog portion and a digital portion.

9. The die of claim 1, further comprising a gap separating said first scribe seal from said second scribe seal.

10. A method of manufacturing a die, said method comprising:
(a) laying a first scribe seal around an integrated circuit on a common substrate; and
(b) laying a second scribe seal around said first scribe seal on said common substrate.

11. The method of claim 10, wherein said (a) comprises laying a first plurality of layers, and said (b) comprises laying a second plurality of layers, wherein said first plurality of layers are laid differently than said second plurality of layers on said die.

12. The method of claim 10, wherein said (a) prevents entry of mobile ions into said integrated circuit, said (b) provides mechanical strength to said die, and both of said first scribe seal and said second scribe seal provide respective high resistance paths along said common substrate.

13. The method of claim 12, wherein (a) comprises:
laying a thin metal layer to provide high resistance path; and
laying a metal layer and a via layer, which together form a continuous path through an oxide layer.

14. The method of claim 13, wherein said (a) comprises laying a thick metal layer providing mechanical strength to said die, wherein said thick metal layer is not connected to said common substrate to provide high resistance path to said common substrate.

15. The method of claim 14, wherein a diffusion layer is not laid in said (b) in a portion corresponding to said second scribe seal.

16. The method of claim 15, wherein a contact layer is not laid in said (b) in a portion corresponding to said second scribe seal.

17. The die of claim 14, wherein said integrated circuit comprises an analog portion and a digital portion.

18. The method of claim 10, further comprising providing a gap between said first scribe seal and said second scribe seal.
